(19) United States
(12) Patent Application Publication
(10) Pub. No.: US 2026/0052799 A1
(43) Pub. Date: Feb. 19, 2026

(54) WAVEGUIDE-TYPE LIGHT-RECEIVING DEVICE

(71) Applicant: Mitsubishi Electric Corporation, Tokyo (JP)

(72) Inventor: Daiki TSUBOUCHI, Tokyo (JP)

(73) Assignee: Mitsubishi Electric Corporation, Tokyo (JP)

(21) Appl. No.: 19/101,576

(22) PCT Filed: Dec. 1, 2022
(86) PCT No.: PCT/JP2022/044393

§ 371 Date: Feb. 5, 2025

(51) Int. Cl. H10F 77/40; H10F 30/223; H10F 77/124

(52) U.S. Cl. CPC H10F 77/413; H10F 30/223; H10F 77/1248

(57) ABSTRACT

The present disclosure relates to a waveguide-type light-receiving device. An object of the present disclosure is to provide a waveguide-type light-receiving device that can perform efficient photoelectric conversion on incident light, and thus can increase light-receiving sensitivity. A waveguide-type light-receiving device of the present disclosure includes a light-absorbing layer that subjects incident light to photoelectric conversion, and a semiconductor embedding layer in which the light-absorbing layer is embedded. A light-incidence-side end face of the light-absorbing layer forms an angle not parallel with a light-incidence-side end face of the semiconductor embedding layer. The refractive index of the semiconductor embedding layer is lower than the refractive index of the light-absorbing layer.

### FIELD

The present disclosure relates to a waveguide-type light-receiving device.

### BACKGROUND

The capacity of communication systems has been increased with a significant increase in communication capacity. Thus, high-speed operation of optical communication devices is required correspondingly. Regarding a photodiode that is a semiconductor light-receiving device used in an optical communication device, a CR time constant is known as a factor that determines the response speed. The CR time constant is determined by the element capacitance C and the element resistance R of the semiconductor light-receiving device. The CR time constant needs to be set small to increase the response speed.

To reduce the element capacitance C, a waveguide-type light-receiving device is adopted. The waveguide-type light-receiving device differs from a common plane-incident structure in that such an element has a structure in which light is allowed to become incident on a side face of an epitaxial growth layer, and can individually optimize sensitivity and the band. Therefore, the structure of such an element is suitable for high-speed operation. Using a waveguide-type light-receiving device can obtain a photodiode with fast responsiveness that is greater than or equal to 40 GHz, for example.

A loaded light-receiving device, which is a type of waveguide-type light-receiving device, has an optical waveguide formed in a region of up to a cleaved end face. Specifically, light is allowed to enter the waveguide, and is then guided to a light-absorbing layer formed at a position away from the light incident portion by a distance of greater than or equal to several μm. In the light-absorbing layer, evanescent light that has seeped out of a guide layer in its thickness direction is subjected to photoelectric conversion (for example, see PTL 1).

As described above, photoelectric conversion is performed indirectly in a loaded light-receiving device. This can reduce the concentration of photocurrent around an end face on which light becomes incident. Therefore, there is an advantage in that even when high-intensity light enters the element, the element is unlikely to have a decreased response speed. Meanwhile, such a loaded light-receiving device has a drawback in that since photoelectric conversion is performed on light that has seeped out of a guide layer in its thickness direction, it is difficult, in principle, to obtain high sensitivity.

To overcome such a drawback, for example, a waveguide-type light-receiving device is known that has a structure in which a light-absorbing layer and the like are embedded in a semiconductor embedding layer.

### CITATION LIST

### Patent Literature

[PTL 1] JP 2003-332613 A

### SUMMARY

### Technical Problem

In a waveguide-type light-receiving device of a conventional technology, the length of a light-absorbing layer, which absorbs light, in the guiding direction (hereinafter referred to as a “waveguide length”) and the thickness of the light-absorbing layer in the stacked direction of semiconductors are controlled to increase light-receiving sensitivity. However, performing such control alone has been insufficient to allow the light to be entirely absorbed by the light-absorbing layer, resulting in decreased light-receiving sensitivity.

The present disclosure has been made to solve the foregoing problem, and it is an object of the present disclosure to provide a waveguide-type light-receiving device that can perform efficient photoelectric conversion on incident light, and thus can increase light-receiving sensitivity.

### Solution to Problem

An aspect of the present disclosure is preferably a waveguide-type light-receiving device comprising:
a light-absorbing layer that subjects incident light to photoelectric conversion; and
a semiconductor embedding layer having embedded therein the light-absorbing layer,
wherein a light-incidence-side end face of the light-absorbing layer forms an angle not parallel with a light-incidence-side end face of the semiconductor embedding layer, and
a refractive index of the semiconductor embedding layer is lower than a refractive index of the light-absorbing layer.

### Advantageous Effects of the Invention

According to the aspect of the present disclosure, a waveguide-type light-receiving device can be provided that can perform efficient photoelectric conversion on incident light, and thus can increase light-receiving sensitivity.

### BRIEF DESCRIPTION OF DRAWINGS

FIG. 1 is an exemplary configuration of a waveguide-type light-receiving device according to Embodiment 1 of the present disclosure.

FIG. 2 is a cross-sectional view of the waveguide-type light-receiving device according to Embodiment 1 of the present disclosure taken along a plane perpendicular to the axis of the incident light.

FIG. 3 is a view of the waveguide-type light-receiving device according to Embodiment 1 of the present disclosure as seen from the surface side.

FIG. 4 is a stereoscopic view of the waveguide-type light-receiving device according to Embodiment 1 of the present disclosure.

FIG. 5 illustrates a modified example of the waveguide-type light-receiving device according to Embodiment 1 of the present disclosure.

FIG. 6 illustrates a modified example of the waveguide-type light-receiving device according to Embodiment 1 of the present disclosure.

FIG. 7 is a cross-sectional view including the light-absorbing layer of the waveguide-type light-receiving device according to Embodiment 1 of the present disclosure.

FIG. 8 is a view illustrating a waveguide-type light-receiving device according to a comparative example of the present disclosure.

FIG. 9 is a graph representing the relationship between the light-receiving sensitivity and the response speed of the waveguide-type light-receiving device.

FIG. 10 is a cross-sectional view including a light-absorbing layer of a waveguide-type light-receiving device according to Embodiment 2 of the present disclosure.

FIG. 11 is a cross-sectional view including a light-absorbing layer of a waveguide-type light-receiving device according to Embodiment 3 of the present disclosure.

FIG. 12 is a cross-sectional view including a light-absorbing layer of a waveguide-type light-receiving device according to Embodiment 4 of the present disclosure.

FIG. 13 is a cross-sectional view including a light-absorbing layer of a waveguide-type light-receiving device according to Embodiment 5 of the present disclosure.

### DESCRIPTION OF EMBODIMENTS

### Embodiment 1

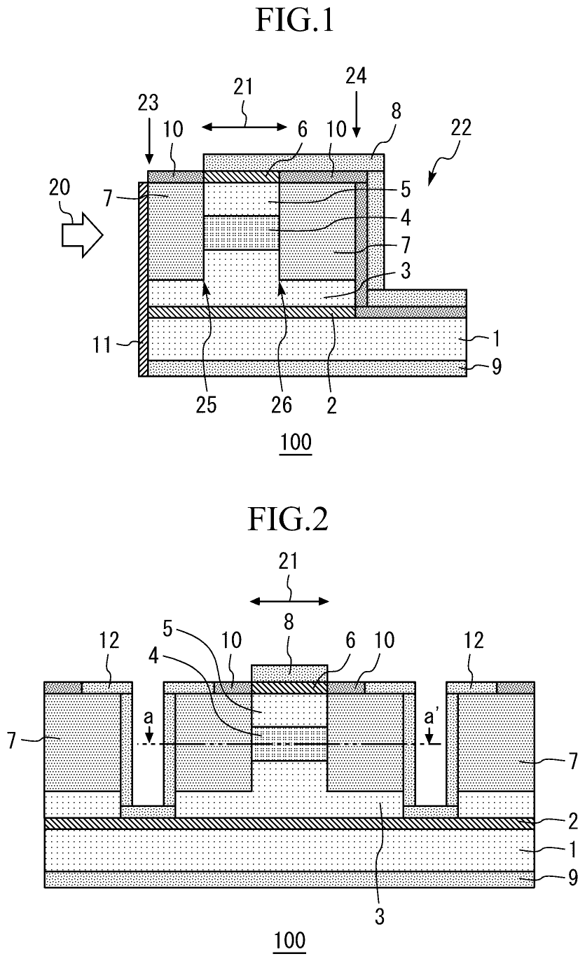

FIG. 1 is an exemplary configuration of a waveguide-type light-receiving device according to Embodiment 1 of the present disclosure. Herein, the upward direction on the sheet surface represents the direction in which semiconductors are stacked, and the rightward direction on the sheet surface represents the axial direction of incident light. In FIG. 1, a waveguide-type light-receiving device 100 has a structure in which an n-type contact layer 2, an n-type clad layer 3, a light-absorbing layer 4 containing InGaAs, a p-type clad layer 5, and a p-type contact layer 6 are stacked in this order on an InP substrate 1. In addition, the n-type clad layer 3, the light-absorbing layer 4, and the p-type clad layer 5 are included in a ridge structure 21. Note that the ridge structure 21 may include at least the light-absorbing layer 4.

A semiconductor embedding layer 7 is a layer in which the ridge structure 21 is embedded.

A light-incidence-side end face 23 of the semiconductor embedding layer 7 is an end face of the semiconductor embedding layer 7 on which incident light 20 becomes incident before it enters the light-absorbing layer 4. The light-incidence-side end face 23 is formed by cleavage, for example. The light-incidence-side end face 23 is covered with an antireflection film 11. However, the light-incidence-side end face 23 need not be entirely covered with the antireflection film 11, and at least a portion of the light-incidence-side end face 23 on which light becomes incident may be covered with the antireflection film 11.

A light-emergence-side end face 24 of the semiconductor embedding layer 7 is an end face from which light, which has entered the semiconductor embedding layer 7 from the light-absorbing layer 4, emerges. Light, which has not been absorbed by the light-absorbing layer 4, reaches the light-emergence-side end face 24.

An etched portion 22 is a portion obtained by partially removing the semiconductor embedding layer 7 on the side of the light-emergence-side end face 24 by etching down to at least the InP substrate 1.

A light-incidence-side end face 25 of the light-absorbing layer 4 is an end face of the light-absorbing layer 4 on which the incident light 20 becomes incident. A light-emergence-side end face 26 of the light-absorbing layer 4 is an end face of the light-absorbing layer 4 from which

A passivation film 10 is a film covering the light-emergence-side end face 24 of the waveguide-type light-receiving device 100 as well as a portion of the surface other than the p-type contact layer 6, a p-type electrode metal 8, and an n-type electrode metal 12 described below.

The p-type electrode metal 8 is an electrode layer formed to be electrically connected to the p-type contact layer 6. As the light-emergence-side end face 24 is covered with the passivation film 10 and the p-type electrode metal 8, it is possible to allow portions of light, which have not been absorbed by the light-absorbing layer 4 and thus have passed therethrough, to be reflected.

A back side metal 9 is a metal film partially or entirely covering the back side of the InP substrate 1.

FIG. 2 is a cross-sectional view of the waveguide-type light-receiving device according to Embodiment 1 of the present disclosure taken along a plane perpendicular to the axis of the incident light. Herein, the upward direction on the sheet surface represents the direction in which semiconductors are stacked, and the left-right direction on the sheet surface represents the width direction of the waveguide in the light-absorbing layer 4. The foregoing ridge structure 21 is also embedded in the semiconductor embedding layer 7 in the cross-section of FIG. 2. The p-type electrode metal 8 and the p-type contact layer 6 are each formed on the ridge structure 21 while having the same width as a ridge portion of the ridge structure 21.

The n-type electrode metal 12 is formed to cover a region of from the surface of the waveguide-type light-receiving device 100 to the n-type contact layer 2. Accordingly, the n-type electrode metal 12 can be electrically in contact with the n-type contact layer 2 from the surface side. The foregoing passivation film 10 is formed to fill the gap between the p-type electrode metal 8 and the n-type electrode metal 12. This can obtain insulation between the electrode metals.

Hereinafter, an example of a method for manufacturing the waveguide-type light-receiving device 100 will be described still with reference to FIGS. 1 and 2. As a growth method for each semiconductor layer of the waveguide-type light-receiving device 100, a liquid phase epitaxy (LPE) or vapor phase epitaxy (VPE) is used, for example. In particular, metal organic VPE (MO-VPE) and molecular beam epitaxy (MBE) are often used, for example.

After the crystals of each semiconductor layer are grown with the foregoing growth method, a mask of an insulating film is formed using a common lithography technique. Further, portions of the semiconductor layers not covered with the mask of the insulating film are etched down to a region in the n-type clad layer 3 so that the ridge structure 21 is obtained. For the etching, dry etching, such as reactive ion etching (RIE), or wet etching is used, for example.

After that, the semiconductor embedding layer 7 is formed on a side face of the ridge structure 21. Herein, a crystal growth method, such as MO-VPE, is used.

Further, a mask of an insulating film covering the ridge structure 21 is formed using a common lithography technique. Then, portions of the semiconductor layers not covered with the mask of the insulating film are etched down to at least the InP substrate 1 so that the etched portion 22 is obtained. For the etching, dry etching, such as RIE, is used, for example.

Further, the passivation film 10 is formed. Specifically, first, an insulating film is deposited uniformly using a method, such as plasma-enhanced chemical vapor deposition (PE-CVD) or sputtering. Further, a mask is left only at the desired portion using a common lithography technique, and unnecessary portions are etched so that the passivation film 10 is obtained.

Further, the semiconductor embedding layer 7 is partially etched down to the n-type contact layer 2. Accordingly, the n-type contact layer 2 can be exposed. For the etching, dry etching, such as RIE, or wet etching is used.

Further, the p-type electrode metal 8 and the n-type electrode metal 12 are formed. Specifically, first, openings are formed in a mask only at the desired positions using a common lithography technique. Further, a material, such as Ti, Pt, or Au, is deposited using a method, such as electron beam vapor deposition or sputtering. Furthermore, unnecessary portions of the metal are removed so that the p-type electrode metal 8 and the n-type electrode metal 12 can be formed.

Alternatively, the p-type electrode metal 8 and the n-type electrode metal 12 may also be formed by depositing a metal, such as Ti, Pt, or Au, on the entire surface, and then leaving a mask at only the desired positions using a common lithography technique, and further removing unnecessary portions of the metal by wet etching.

Further, the back side metal 9 is formed. Specifically, the InP substrate 1 is flipped, and an opening is formed in a mask only at the desired position using a common lithography technique. Further, a material, such as Ti, Pt, or Au, is deposited using a method, such as electron beam vapor deposition or sputtering. Furthermore, unnecessary portions of the metal are removed so that the back side metal 9 can be formed.

Alternatively, the back side metal 9 may also be formed by depositing a metal, such as Ti, Pt, or Au, on the entire surface, and then leaving a mask only at the desired position using a common lithography technique, and further removing unnecessary portions of the metal by wet etching.

The antireflection film 11 is formed on the light-incidence-side end face 23 by vapor deposition or sputtering in a state where the chip is cleaved.

Hereinafter, preferred materials of the waveguide-type light-receiving device 100 will be described still with reference to FIGS. 1 and 2. Note that any material may be used for each layer as long as the characteristics required of the operation of the waveguide-type light-receiving device are obtained. Thus, the technical scope of the present disclosure is not limited by the following materials.

The InP substrate 1 is desirably a semi-insulating substrate doped with Fe, for example. The material of the n-type contact layer 2 may be InGaAs, InP, InGaAsP, AlInAs, AlGaInAs, or a combination thereof. The material of the n-type clad layer 3 may be InP, InGaAsP, AlInAs, AlGaInAs, or a combination thereof.

The material of the light-absorbing layer 4 may be not only InGaAs but also InGaAsP, InGaAsSb, or a combination thereof as long as it is a material in which carriers are generated when light enters the light-absorbing layer 4, that is, a material with a small bandgap relative to the incident light 20.

The material of the p-type clad layer 5 may be InP, InGaAsP, AlInAs, AlGaInAs, or a combination thereof. The material of the p-type contact layer 6 may be InGaAs, InP, InGaAsP, AlInAs, AlGaInAs, or a combination thereof. The material of the semiconductor embedding layer 7 may be InP or InGaAsP, for example, which may be further doped with Fe or Ru.

To alleviate band discontinuity, a band discontinuity alleviation layer containing InGaAsP or AlGaInAs, for example, may be provided between adjacent epitaxial layers or between the p-type electrode metal 8 and an epitaxial layer.

The material of the passivation film 10 may be SiO₂, SiN, SiON, or a combination thereof.

As p-type dopants that impart electrical conductivity to the group III-V semiconductor crystals, group II atoms, such as Be, Mg, Zn, and Cd, are used. As n-type dopants, group VI atoms, such as S, Se, and Te, are used. As amphoteric impurities that act as dopants of either conductivity type depending on the semiconductor crystals used, group IV atoms, such as C, Si, Ge, and Sn, are used. Meanwhile, atoms, such as Fe and Ru, function as insulating dopants that impart a semi-insulating (SI) property by suppressing electrical conductivity.

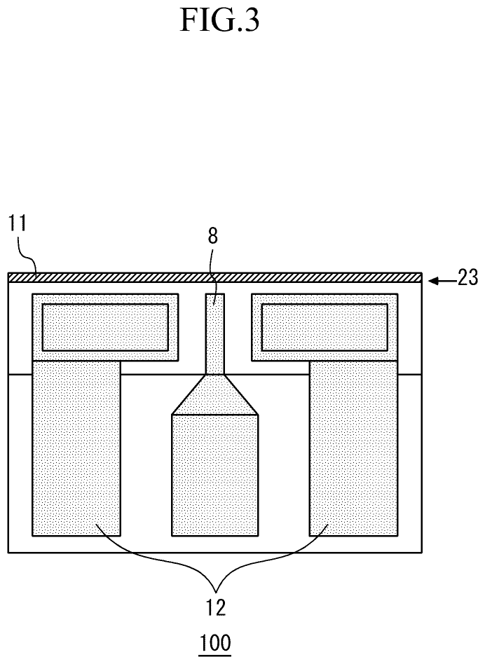

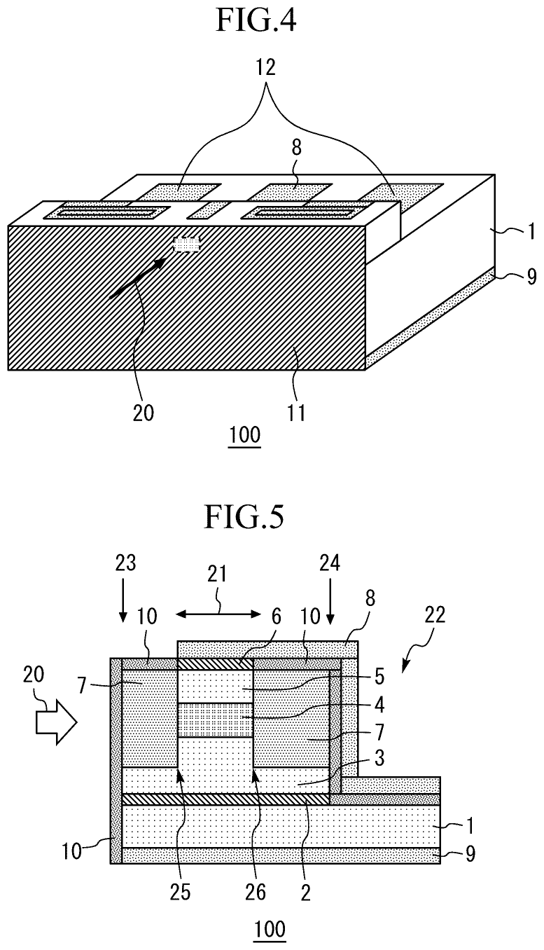

FIG. 3 is a view of the waveguide-type light-receiving device according to Embodiment 1 of the present disclosure as seen from the surface side. FIG. 4 is a stereoscopic view of the waveguide-type light-receiving device according to Embodiment 1 of the present disclosure.

### Modified Examples

Hereinafter, modified examples of the waveguide-type light-receiving device 100 illustrated in FIGS. 1 to 4 will be described. FIG. 5 illustrates a modified example of the waveguide-type light-receiving device according to Embodiment 1 of the present disclosure. The structure of the waveguide-type light-receiving device 100 in FIG. 5 is similar to that in FIG. 1, but the passivation film 10 is formed instead of the antireflection film 11 on the light-incidence-side end face 23. Such a structure is possible because the passivation film 10 also has an antireflection effect.

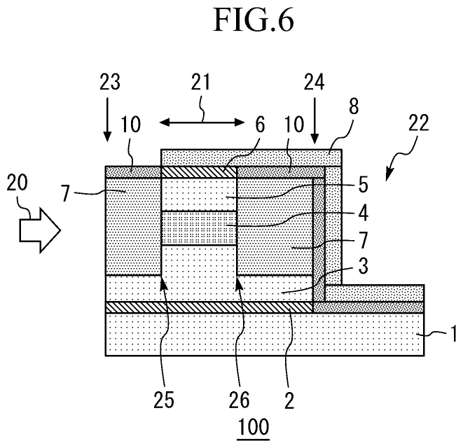

FIG. 6 illustrates a modified example of the waveguide-type light-receiving device according to Embodiment 1 of the present disclosure. The structure of the waveguide-type light-receiving device 100 in FIG. 6 is similar to that in FIG. 1, but the back side metal 9 and the antireflection film 11 on the light-incidence-side end face 23 are removed. As such, the back side metal 9 and the antireflection film 11 need not be provided. However, the antireflection film 11 is desirably formed from the perspective of increasing light-receiving sensitivity.

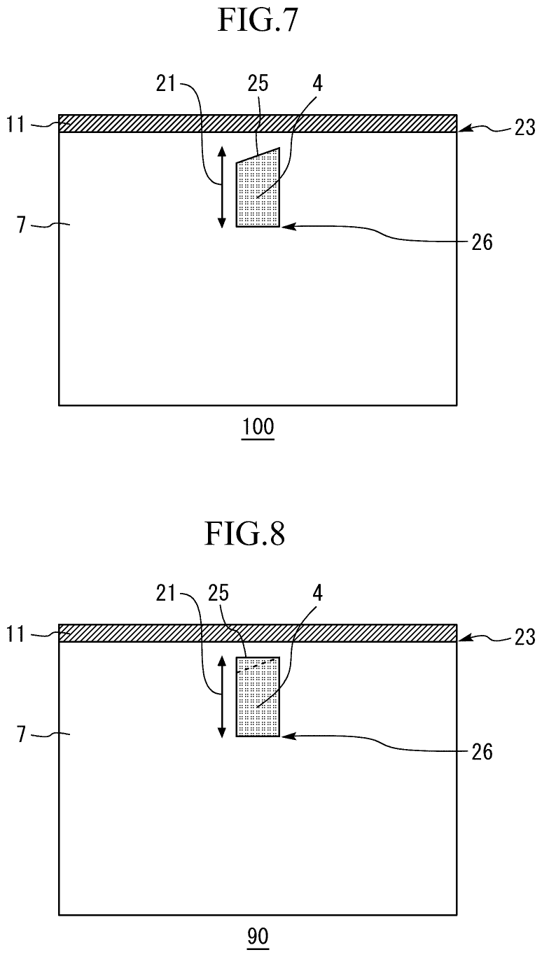

FIG. 7 is a cross-sectional view including the light-absorbing layer of the waveguide-type light-receiving device according to Embodiment 1 of the present disclosure. Herein, a view taken along the direction of arrows a-a′ in FIG. 2 is illustrated. In the waveguide-type light-receiving device 100, the light-incidence-side end face 25 of the light-absorbing layer 4 forms an angle not parallel with the light-incidence-side end face 23 of the semiconductor embedding layer 7.

As a comparative example for describing the advantageous effects of the present disclosure, a conventional technology will be described hereinafter. FIG. 8 is a view illustrating a waveguide-type light-receiving device according to a comparative example of the present disclosure. The direction of arrows along which the view is taken is the same as that of FIG. 7. In a waveguide-type light-receiving device 90 of the conventional technology, the light-incidence-side end face 25 of the light-absorbing layer 4 is parallel with the light-incidence-side end face 23 of the semiconductor embedding layer 7. In such a case, light, which has passed through the light-incidence-side end face 23 of the semiconductor embedding layer 7 and reached the light-incidence-side end face 25 of the light-absorbing layer 4, travels straight ahead through the light-absorbing layer 4 without changing direction.

Referring back to FIG. 7, the advantageous effects of the present disclosure will be described. In the waveguide-type light-receiving device 100, light, which has passed through the light-incidence-side end face 23 of the semiconductor embedding layer 7 and reached the light-incidence-side end face 25 of the light-absorbing layer 4, is refracted by the light-incidence-side end face 25 of the light-absorbing layer 4. Since the refractive index of the light-absorbing layer 4 is higher than the refractive index of the semiconductor embedding layer 7, the refracted light is guided through the light-absorbing layer 4 while being totally reflected by the interface between the light-absorbing layer 4 and the semiconductor embedding layer 7. The optical path length at this time is greater than that of the conventional technology in which light just travels straight ahead, by the amount of the travel of the light through the light-absorbing layer 4 involving total reflection. Thus, the distance for which photoelectric conversion occurs becomes longer correspondingly, resulting in increased light-receiving sensitivity.

As described above, in the waveguide-type light-receiving device 100 of the present disclosure, the light-incidence-side end face 25 of the light-absorbing layer 4 forms an angle not parallel with the light-incidence-side end face 23 of the semiconductor embedding layer 7. This can increase the optical path length of light traveling through the light-absorbing layer 4, and thus can increase light-receiving sensitivity.

As described above, in the waveguide-type light-receiving device 90 of the conventional technology, only the waveguide length of the light-absorbing layer 4 and the thickness of the light-absorbing layer 4 in the stacked direction of semiconductors are controlled to increase light-receiving sensitivity. In the present disclosure, the angle formed by the light-incidence-side end face 25 of the light-absorbing layer 4 and the light-incidence-side end face 23 of the semiconductor embedding layer 7 is controlled so that a further improvement of light-receiving sensitivity is achieved.

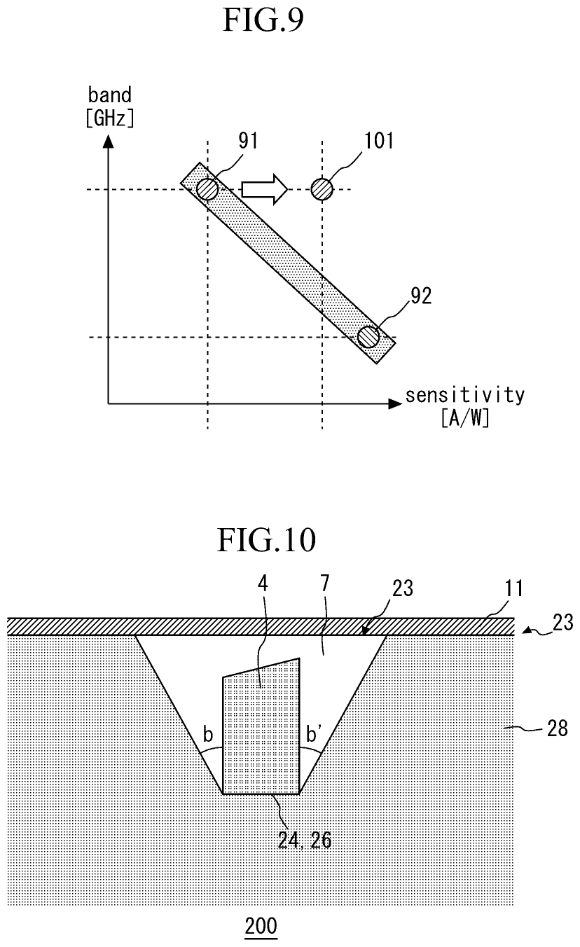

FIG. 9 is a graph representing the relationship between the light-receiving sensitivity and the response speed of the waveguide-type light-receiving device. The abscissa axis represents the light-receiving sensitivity, where the unit is A/W, for example. The ordinate axis represents the band, where the unit is GHz, for example. Regarding the waveguide-type light-receiving device of the conventional technology in which only the waveguide length of the light-absorbing layer 4 and the thickness of the light-absorbing layer 4 in the stacked direction of semiconductors are controlled, it is known that the light-receiving sensitivity and the band have a trade-off relationship. That is, with the conventional technology, the waveguide-type light-receiving device 90 is obtained that has characteristics represented by a straight line connecting points 91 and 92.

Meanwhile, the waveguide-type light-receiving device 100 of the present disclosure can eliminate the trade-off relationship between the light-receiving sensitivity and the response speed of the conventional technology. That is, the waveguide-type light-receiving device 100 can be obtained that has the same degree of response characteristics as the waveguide-type light-receiving device of the conventional technology, and has high light-receiving sensitivity as indicated by a point 101.

### Embodiment 2

FIG. 10 is a cross-sectional view including a light-absorbing layer of a waveguide-type light-receiving device according to Embodiment 2 of the present disclosure. A waveguide-type light-receiving device 200 of this embodiment has a structure obtained by changing the structure of a portion around the light-absorbing layer 4 in FIG. 7. Meanwhile, the structure of the waveguide-type light-receiving device 200 is the same as that in FIG. 7 in terms of points other than the structure of the a-a′ cross-section in FIG. 2. This also holds true for the following embodiments.

The waveguide-type light-receiving device 200 further includes a low-refractive-index material layer 28 in which the semiconductor embedding layer 7 is embedded. As the semiconductor embedding layer 7 is embedded in the low-refractive-index material layer 28, the area of the light-incidence-side end face 23 of the semiconductor embedding layer 7 becomes larger than the area of the light-emergence-side end face 24. The refractive index of the low-refractive-index material layer 28 is lower than the refractive index of the semiconductor embedding layer 7. Accordingly, it is possible to allow light, which has become incident on the light-incidence-side end face 23 of the semiconductor embedding layer 7 and has traveled straight ahead, but has not entered the light-absorbing layer 4, to be totally reflected by the interface between the semiconductor embedding layer 7 and the low-refractive-index material layer 28. Changing the travel path of light, which has not directly entered the light-absorbing layer 4, such that the light takes a path through the light-absorbing layer 4 can increase the amount of light that contributes to increasing light-receiving sensitivity, and thus can increase the light-receiving sensitivity more than in Embodiment 1.

Herein, to allow light to enter a waveguide-type light-receiving device, a spherical lensed fiber (also referred to as a lensed fiber) or an incident optical component, such as a condensing module, is typically used. However, when light is allowed to become incident on an end face of the waveguide-type light-receiving device, it would be difficult to allow the light to entirely enter a light-absorbing layer without any waste due to restrictions in terms of the characteristics or implementation of the incident optical component. Light that has not entered the light-absorbing layer is not subjected to photoelectric conversion, which results in a further decrease in the light-receiving sensitivity. This embodiment can overcome such a drawback because light that has not directly entered the light-absorbing layer 4 is also subjected to photoelectric conversion.

As the material of the low-refractive-index material layer 28, an organic resin material, such as polyimide or BCB (Benzo Cyclo Butene), can be used.

Each of angles b and b′ made by side faces of the light-absorbing layer 4 and side faces of the semiconductor embedding layer 7 is not limited to a particular angle. In addition, the semiconductor embedding layer 7 may also be embedded in the gap between the light-emergence-side end face 26 of the light-absorbing layer 4 and the low-refractive-index material layer 28.

### Embodiment 3

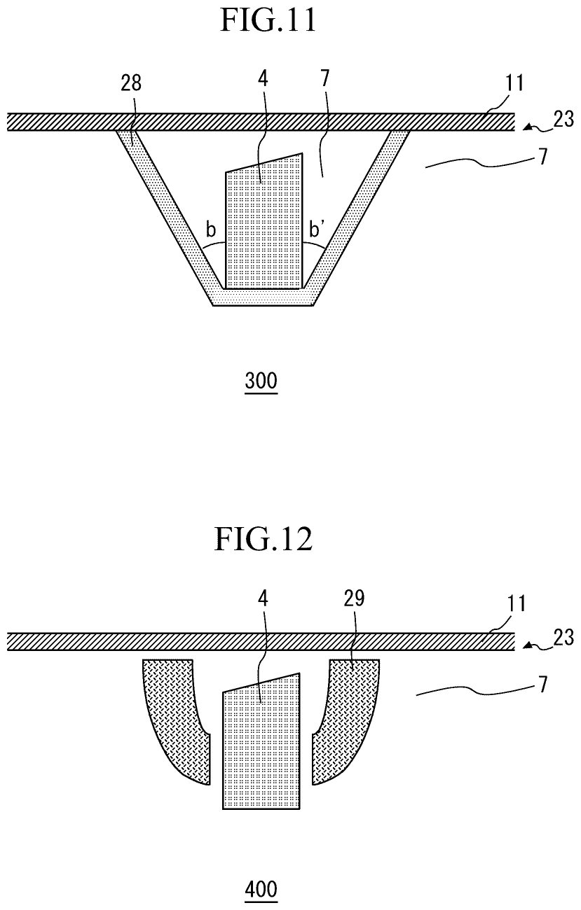

FIG. 11 is a cross-sectional view including a light-absorbing layer of a waveguide-type light-receiving device according to Embodiment 3 of the present disclosure. A waveguide-type light-receiving device 300 has a structure obtained by further embedding the outer side of the low-refractive-index material layer 28 of Embodiment 2 in the semiconductor embedding layer 7. When an organic resin material, such as polyimide or BCB, is used for the low-refractive-index material layer 28, the characteristics of the waveguide-type light-receiving device may degrade because such a material has thermal conductivity lower than those of semiconductor materials, and also has poor heat radiation characteristics. In this embodiment, portions embedded in the low-refractive-index material layer 28 are limited to particular portions. Thus, a structure that is more advantageous than the structure of Embodiment 2 in terms of heat radiation characteristics is achieved.

### Embodiment 4

FIG. 12 is a cross-sectional view including a light-absorbing layer of a waveguide-type light-receiving device according to Embodiment 4 of the present disclosure. A waveguide-type light-receiving device 400 includes an optical waveguide layer 29, which has a bandgap wavelength higher than the wavelength of the incident light 20, on the lateral portions of the light-absorbing layer 4. Accordingly, it is possible to allow light, which has become incident on the light-incidence-side end face 23 of the semiconductor embedding layer 7 and has traveled straight ahead, but has not entered the light-absorbing layer 4, to be at least partially guided toward the light-absorbing layer 4. This can increase light-receiving sensitivity.

### Embodiment 5

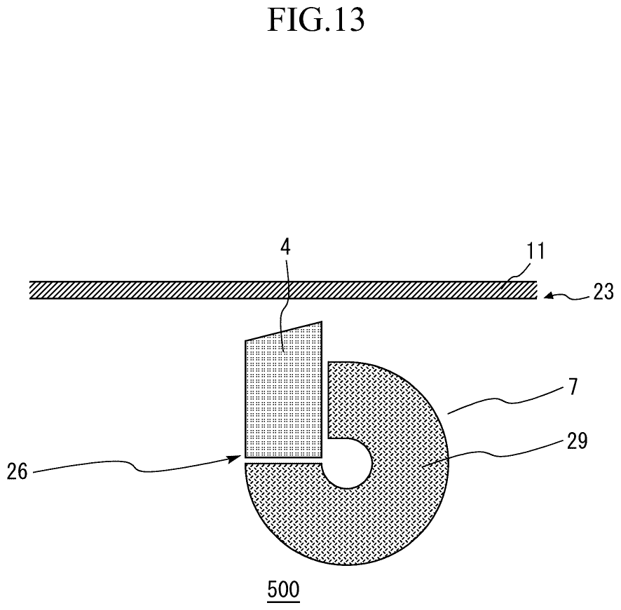

FIG. 13 is a cross-sectional view including a light-absorbing layer of a waveguide-type light-receiving device according to Embodiment 5 of the present disclosure. A waveguide-type light-receiving device 500 further includes an optical waveguide layer 29 for allowing light, which has come out of the light-emergence-side end face 26 of the light-absorbing layer 4, to enter the light-absorbing layer 4 again. Accordingly, since light that has come out of the light-emergence-side end face 26 can be reused, light-receiving sensitivity can be increased.

As described above, according to the present disclosure, a waveguide-type light-receiving device can be provided that can perform efficient photoelectric conversion on incident light, and thus can increase light-receiving sensitivity.

### Correspondence of Terminologies to Those Used in the Claims

As described in Embodiments 2 to 4, the light-incidence-side end face 23 of the semiconductor embedding layer 7 has a region that does not allow light, which has traveled straight ahead from the light-incidence-side end face 23, to reach the light-absorbing layer 4. Such a region is referred to as a second region in the claims. Conversely, a region that allows light, which has traveled straight ahead from the light-incidence-side end face 23, to reach the light-absorbing layer 4 is referred to as a first region.

### Reference Signs List

InP substrate 1; n-type contact layer 2; n-type clad layer 3; light-absorbing layer 4; p-type clad layer 5; p-type contact layer 6; semiconductor embedding layer 7; p-type electrode metal 8; back side metal 9; passivation film 10; antireflection film 11; n-type electrode metal 12; incident light 20; ridge structure 21; etched portion 22; light-incidence-side end face 23; light-emergence-side end face 24; light-incidence-side end face 25; light-emergence-side end face 26; low-refractive-index material layer 28; optical waveguide layer 29; conventional technology waveguide-type light-receiving device 90; point 91; point 92; waveguide-type light-receiving device 100; point 101; waveguide-type light-receiving device 200; waveguide-type light-receiving device 300; waveguide-type light-receiving device 400; waveguide-type light-receiving device 500

1. A waveguide-type light-receiving device comprising:
a light-absorbing layer that subjects incident light to photoelectric conversion;
a semiconductor embedding layer having embedded therein the light-absorbing layer; and
a low-refractive-index material layer having embedded therein the semiconductor embedding layer,
wherein a light-incidence-side end face of the light-absorbing layer forms an angle not parallel with a light-incidence-side end face of the semiconductor embedding layer,
a refractive index of the semiconductor embedding layer is lower than a refractive index of the light-absorbing layer,
a refractive index of the low-refractive-index material layer is lower than the refractive index of the semiconductor embedding layer, and
an area of the light-incidence-side end face of the semiconductor embedding layer is larger than an area of a light-emergence-side end face of the semiconductor embedding layer.

2. The waveguide-type light-receiving device according to claim 1, further comprising a semiconductor embedding layer having embedded therein the low-refractive-index material layer.

3.-5. (canceled)
